(19) United States
(12) Patent Application Publication
(10) Pub. No.: US 2026/0198255 A1
(43) Pub. Date: Jul. 9, 2026

(54) MONITORING SYSTEM AND METHOD OF MEASURING PROCESS PARAMETER IN THE SAME

(71) Applicants: WIT CORPORATION, Hwaseong-si (KR); FINE SEMITECH CORP., Hwaseong-si (KR)

(72) Inventors: Jae Hwan KIM, Hwaseong-si (KR); Jae Won OH, Gunpo-si (KR)

(21) Appl. No.: 19/369,054

(22) Filed: Oct. 24, 2025

Related U.S. Application Data
(63) Continuation of application No. PCT/KR2023/013815, filed on Sep. 14, 2023.

(30) Foreign Application Priority Data
Jun. 8, 2023 (KR) 10-2023-0073640

(51) Int. Cl. H10P 72/00; H01J 37/32; H10P 72/76

(52) U.S. Cl. CPC H10P 72/0604; H01J 37/32642; H01J 37/32724; H01J 37/32926; H01J 37/32935; H10P 72/0602; H10P 72/7611

(57) ABSTRACT

A first monitoring device used in a monitoring system comprises a sensor configured to measure a process parameter, a communication unit and a controller. Here, the first monitoring device is located on an object to be monitored and measures the process parameter of the object using the sensor, an edge ring is disposed outside the object, the controller transmits a measurement recipe command for requesting measuring of a process parameter of the edge ring to the edge ring or a second monitoring device for measuring the process parameter of the edge ring through the communication unit, and the measurement recipe command is a command of controlling the edge ring or the second monitoring device so that the edge ring or the second monitoring device measures the process parameter of the edge ring.

### CROSS-REFERENCE TO RELATED APPLICATIONS

This application is a bypass continuation of pending PCT International Application No. PCT/KR 2023/013815, which was filed on Sep. 14, 2023, and which claims priority under 35 U.S.C 119(a) to Korean Patent Application No. 10-2023-0073640 filed with the Korean Intellectual Property Office on Jun. 8, 2023. The disclosures of the above patent applications are incorporated herein by reference in their entirety.

### TECHNICAL FIELD

The present disclosure relates to a monitoring system and a method of measuring a process parameter in the same.

### BACKGROUND ART

The structure of a semiconductor device has been changed from a planar structure to 3D structure. A critical dimension of the semiconductor device becomes smaller in nano-level, and thus it is becoming harder to manufacture the semiconductor device.

Accordingly, temperature of a wafer should be precisely controlled. However, it is difficult to control temperature of an edge part of the wafer because an edge of the wafer contacts with vacuum atmosphere of a chamber and size of an electrostatic chuck is smaller than that of the wafer.

A circular edge ring located outside the wafer is used to control more precisely temperature distribution of the wafer as shown in FIG. 1. Additionally, a heater is disposed below the edge ring to control temperature of the edge ring.

However, a technique of accurately measuring the temperature distribution of an edge of the wafer does not exist yet, and thus it is impossible to precisely control the wafer.

### SUMMARY

The present disclosure is to provide a monitoring system and a method of measuring a process parameter in the same.

A first monitoring device used in a monitoring system according to an embodiment of the present disclosure comprises a sensor configured to measure a process parameter; a communication unit; and a controller. Here, the first monitoring device is located on an object to be monitored and measures the process parameter of the object using the sensor. An edge ring is further disposed outside the object, and the controller transmits a measurement recipe command for requesting measuring of a process parameter of the edge ring to the edge ring or a second monitoring device for measuring the process parameter of the edge ring through the communication unit, and the measurement recipe command is a command of controlling the edge ring or the second monitoring device so that the edge ring or the second monitoring device measures the process parameter of the edge ring.

A second monitoring device used in a monitoring system according to an embodiment of the present disclosure comprises a sensor configured to measure a process parameter; a communication unit; and a controller. Here, the second monitoring device is an edge ring disposed outside a chuck and communicates with a first monitoring device for measuring a process parameter of a chuck while disposed on the chuck, the controller controls the sensor to measure the process parameter in response to a measurement recipe command transmitted from the first monitoring device through the communication unit, and transmits measured data concerning the measured process parameter to the first monitoring device or an external device.

A method of measuring a process parameter in a monitoring system which includes a first monitoring device disposed on an object to be monitored and a second monitoring device located outside the object and functioning as an edge ring according to an embodiment of the present disclosure comprises disposing the first monitoring device on the object; transmitting for the first monitoring device a measurement recipe command to the second monitoring device; measuring for the second monitoring device self-process parameter in response to the transmitted measurement recipe command; transmitting second measured data concerning the measured process parameter from the second monitoring device to the first monitoring device; and transmitting for the first monitoring device the transmitted second measured data to an external device.

A method of measuring a process parameter in a monitoring system according to another embodiment of the present disclosure includes measuring for an edge ring self-process parameter using a sensor, the edge ring including at least one sensor and a communication unit; and transmitting for the edge ring measured data concerning the measured process parameter to an external device. Here, the measured data is transmitted to the external device after the edge ring is transferred outside a chamber.

A method of measuring a process parameter according to still another embodiment of the present disclosure includes communication-connecting a station in a cassette to a monitoring device; receiving for the station measured data from the monitoring device, the measured data being data concerning a process parameter of an object in a chamber measured by the monitoring device; and transmitting for the station the received measured data to an external device. Here, the station receives the measured data from the monitoring device while the monitoring device is located in the cassette.

A cassette used in a monitoring system according to an embodiment of the present disclosure includes slits and a station. Here, the monitoring device is laid on the slit and measures a process parameter of an object in a chamber, and the station receives measured data concerning the measured process parameter from the monitoring device and transmits the received measured data to an external device.

A monitoring system and a method of measuring a process parameter according to an embodiment of the present disclosure measure a process parameter of a chuck by using a first monitoring device and measures a self-process parameter by using a second monitoring device (edge ring). As a result, the monitoring system may measure temperature distribution from a central part of a chuck (central part of a wafer) to the edge ring. Accordingly, it is possible to precisely control the temperature of the wafer.

### BRIEF DESCRIPTION OF DRAWINGS

Example embodiments of the present disclosure will become more apparent by describing in detail example embodiments of the disclosure with reference to the accompanying drawings, in which:

FIG. 1 is a view illustrating conventional chamber;

FIG. 2 is a view illustrating a chamber according to an embodiment of the present disclosure;

FIG. 3 and FIG. 4 are views illustrating a first monitoring device according to an embodiment of the present disclosure;

FIG. 5 to FIG. 10 are views illustrating a second monitoring device according to an embodiment of the present disclosure;

FIG. 11 is a flowchart illustrating a process of measuring a process parameter in a monitoring system according to an embodiment of the present disclosure;

FIG. 12 is a flowchart illustrating a process of measuring a process parameter in a monitoring system according to another embodiment of the present disclosure;

FIG. 13 is a sectional view illustrating a wafer cassette according to an embodiment of the present disclosure;

FIG. 14 is a flowchart illustrating operation of the wafer cassette in FIG. 13;

FIG. 15 is a block diagram illustrating a first monitoring device according to an embodiment of the present disclosure; and

FIG. 16 is a block diagram illustrating a second monitoring device according to an embodiment of the present disclosure.

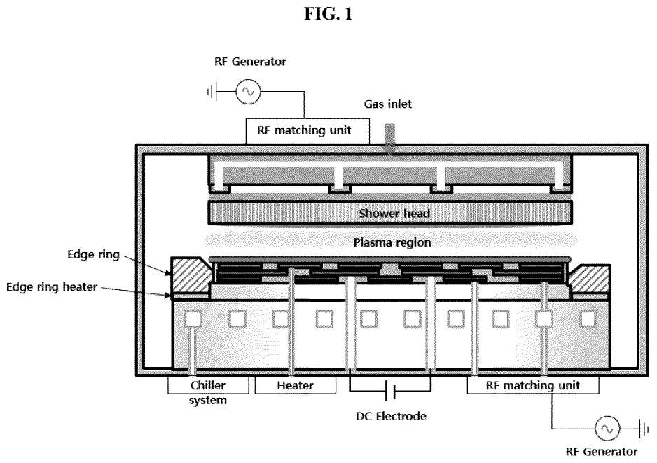

### DETAILED DESCRIPTION

In the present specification, an expression used in the singular encompasses the expression of the plural, unless it has a clearly different meaning in the context. In the present specification, terms such as “comprising” or “including,” etc., should not be interpreted as meaning that all of the elements or operations are necessarily included. That is, some of the elements or operations may not be included, while other additional elements or operations may be further included. Also, terms such as “unit,” “module,” etc., as used in the present specification may refer to a part for processing at least one function or action and may be implemented as hardware, software, or a combination of hardware and software.

The present disclosure relates to a monitoring system and a method of measuring a process parameter in the same. For example, the monitoring system may include a first monitoring device for measuring temperature distribution, slope, etc. of an object to be monitored, e.g. an electrostatic chuck in a semiconductor process or a display process and a second monitoring device for measuring temperature distribution, etc. of an edge ring. Here, the second monitoring device may be the edge ring for self-monitoring its temperature.

The first monitoring device may measure RF voltage, current or power, etc. in a plasma state, and detect finally abnormal of the electrostatic chuck.

In an embodiment, the first monitoring device may be a wafer-type monitoring device, and measure temperature distribution, etc. of a wafer area corresponding to a wafer to be laid on a chuck in following process. The second monitoring device may measure temperature distribution, etc. of the edge ring outside the wafer area. As a result, the monitoring system may measure at a time a process parameter, e.g. temperature distribution from an area corresponding to a central part of the wafer to the edge ring. Accordingly, it is possible to precisely control the temperature of the wafer.

Hereinafter, various embodiments of the present disclosure will be described in detail with reference to accompanying drawings.

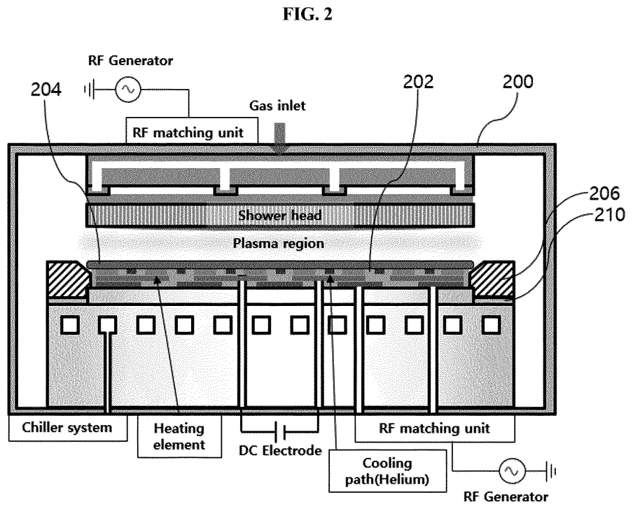

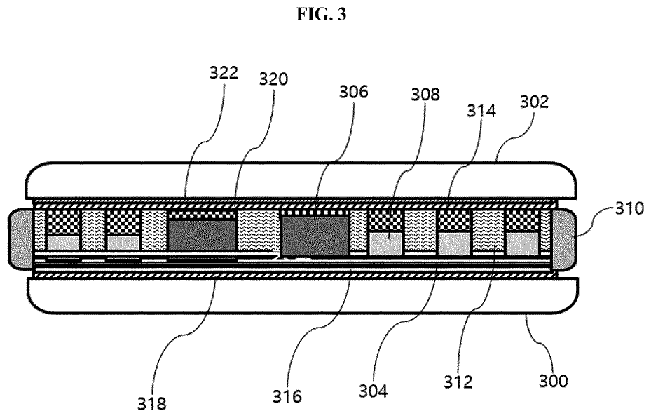

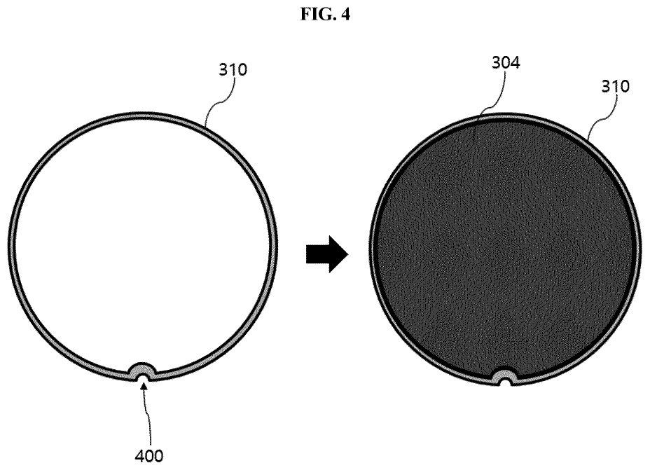

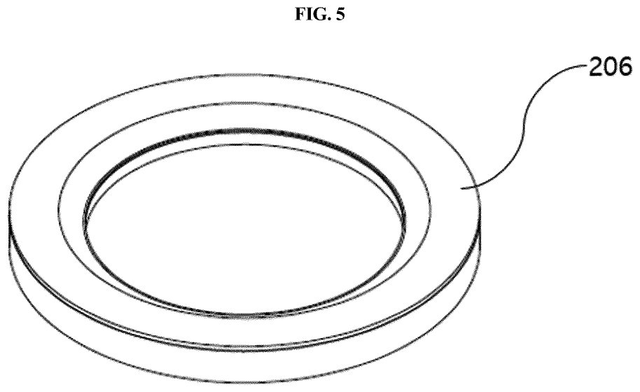

FIG. 2 is a view illustrating a chamber according to an embodiment of the present disclosure, FIG. 3 and FIG. 4 are views illustrating a first monitoring device according to an embodiment of the present disclosure, and FIG. 5 to FIG. 10 are views illustrating a second monitoring device according to an embodiment of the present disclosure.

In FIG. 2, a chuck, e.g. an electrostatic chuck 202 may be located at a lower part of an internal space of the chamber 200 and a shower head may be disposed at an upper part of the internal space.

In an embodiment, a first monitoring device 204 may be disposed on the electrostatic chuck 202, a second monitoring device (edge ring) 206 with, for example, a circular shape may be located outside the electrostatic chuck 202, and a heater 210 may be disposed below the second monitoring device 206. Of course, a heater for heating a wafer may be disposed in the electrostatic chuck 202.

The first monitoring device 204 may measure a process parameter, e.g. temperature distribution of an object to be monitored, e.g. the electrostatic chuck 202, and the second monitoring device 206 may measure its process parameter, e.g. temperature distribution.

Hereinafter, the second monitoring device 206 will be described after the first monitoring device 204 is described.

In FIG. 3, the first monitoring device 204 may include a lower cover 300, an upper cover 302, a circuit module, a guide cover 310, a first filler 312, a second filler 314, a first EMI shielding layer 316, a first adhesive layer 318, a second EMI shielding layer 320 and a second adhesive layer 322. Here, the circuit module includes a PCB substrate 304, an electrical element unit 306 and a sensor 308.

The lower cover 300 may protect elements on the PCB substrate 304 from external surroundings, e.g. plasma environment, and protect the chamber from pollutants generated by the elements.

In an embodiment, the lower cover 300 may have the same circular shape as a wafer, have a planar surface and be formed of silicone or glass, etc. which are materials used frequently in a semiconductor process. In another embodiment, the lower cover 300 may be formed of silicone carbide, sapphire, Y₂O₃, YOF, Al₂O₃ which is ceramic material, Teflon which is engineering plastic, PEEK, carbon fiber and so on.

The lower cover 300 is in direct contact with the electrostatic chuck 202 which is the object, and thus the lower cover 300 may have the same flatness as the wafer.

The upper cover 302 may protect elements on the PCB substrate 304 from external surroundings and be formed of the same material as the lower cover 300 or material similar to the lower cover 300. For example, the upper cover 302 may be formed of silicone, glass, silicone carbide, sapphire, Y₂O₃, YOF, Al₂O₃ which is ceramic material, Teflon which is engineering plastic, PEEK, carbon fiber and so on.

In an embodiment, bending of the lower cover 300 or the upper cover 302 may be less than 100μm, and total thickness variation TTV of the lower cover 300 or the upper cover 302 may be less than 10μm.

The PCB substrate 304 locates between the lower cover 300 and the upper cover 302, and it may be FR-4 or flexible PCB (FPCB).

The electrical element unit 306 is disposed on the PCB substrate 304 and it may include at least one electrical element. For example, the electrical element unit 306 may include a microprocessor, a signal processing device, a wireless communication element or a wireless charging element, etc.

The sensor 308 may be an electrical element and be disposed on the PCB substrate 304. A part of the sensors 308 may be included in the electrical element unit 306 and another sensor 308 may locate outside the electrical element unit 306. That is, location of the sensor 308 is not limited as long as the sensor 308 measures a process parameter, e.g. temperature distribution, etc. and locates on the PCB substrate 304.

In an embodiment, the sensor 308 may be disposed on an area corresponding to an extreme edge. Here, the extreme edge may be an area within 1.5 mm to 3 mm from an edge of the wafer. Of course, this range of the extreme edge depends on a size of the wafer. This is, the first monitoring device 204 may measure feature of an edge area of the electrostatic chuck 202 corresponding to the extreme edge area of the wafer to be used in following processes.

Alternatively, the sensor 308 may also measure feature of a central part of the electrostatic chuck 202 corresponding to a central part of the wafer. That is, one or more sensors 308 may measure parameter, e.g. temperature distribution, etc. of an area corresponding to the central part of the wafer to an area corresponding to the edge area of the object.

The guide cover 310 may locate at a side of the first monitoring device 204 and protects electrical elements, etc. For example, the guide cover 310 may have a circular shape similar to the wafer as shown in FIG. 4.

In an embodiment, a groove (notch) 400 may be formed at a part of the guide cover 310 as shown in FIG. 4, and a groove may be formed at the PCB substrate 304 located inside the guide cover 310. As a result, it can align easily the PCB substrate 304 in the guide cover 310 if the PCB substrate 304 is disposed so that the groove 400 of the guide cover 310 is consistent with the groove of the PCB substrate 304. That is, the groove 400 is a reference point for the alignment.

In an embodiment, common section of the upper cover 302, the guide cover 310 and the lower cover 300 may cool the PCB substrate 304 and the circuit module from a heat source. To perform this function, the upper cover 302, the guide cover 310 and the lower cover 300 may have the same conductivity as silicone or similar conductivity to the silicone.

The guide cover 310 may be formed of the same material as the silicone wafer. In another embodiment, the guide cover 310 may be made up of silicone carbide, sapphire, Al₂O₃, YOF or Y₂O₃ which is ceramic material, or Teflon which is an engineering plastic, PEEK or carbon fiber.

The first filler 312 may be filled between electrical elements of the electrical element unit 306, between the electrical element unit 306 and the sensor 308, between the sensors 308 or between the sensor 308 and the guide cover 310.

In an embodiment, the first filler 312 may be solid, and be formed of the same material as the upper cover 302 or the lower cover 300 or material similar to the upper cover 302 or the lower cover 300. That is, the first filler 312 may have the same heat conductivity as the upper cover 302 or the lower cover 300 or heat conductivity similar to the upper cover 302 or the lower cover 300. As a result, heating by ion bombardment applied at a surface of the upper cover 302 when plasma occurs in the chamber 200 may be accurately sensed.

Si or SiC which is silicone-based material, PEEK, glass, ceramic material, quartz, etc. may be used as the first filler 312 when the first filler 312 is solid, wherein the thermal expansive coefficient of PEEK, glass, ceramic material or quartz is similar to that of Si or SiC. This is to maximize sensitivity of the sensor 308 in view of heat conductivity or heat flux when the temperature is measured.

In another embodiment, the first filler 312 may be liquid. In this case, cured resin, e.g. epoxy or silicone-based material may be used as the first filler 312. To form the first filler 312 with liquid is for compensating step difference of the electrical elements and assuring flatness of the electrical elements because the electrical elements on the PCB substrate 304 have different height. For example, the first filler 312 on the electrical elements or the sensor 308 may be flat by applying a polishing process after filling the first filler 312 on the electrical elements or the sensor 308.

The second filler 314 may be formed on the electrical elements, the sensor 308 or the first filler 312.

In an embodiment, the second filler 314 may be liquid, e.g. be formed of epoxy, silicone-based material or an UV cured material. To form the second filler 314 with liquid is for compensating step difference of the electrical elements and the sensor 308 and assuring flatness of the electrical elements and the sensor 308 because the electrical elements and the sensor 308 have different heights. Alternatively, the second filler 314 may be solid.

In another view, the fillers 312 and 314 may seal the electrical elements and the sensor 308 by covering the electrical elements and the sensor 308.

In an embodiment, top surfaces of the fillers 312 and 314 may be flattened by polishing the top surfaces of the fillers 312 and 314 after filling the first filler 312 or the second filler 314 on an electrical element (including the sensor) with a comparatively low height. In this case, a part more than preset height of the first filler 312 or the second filler 314 may be removed, and a surface of the electrical element may be also polished in a polishing process. That is, the electrical elements and the sensor 308 on which the filler 312 or 314 is filled may have the same height by performing the polishing process after filling the filler 312 or 314 on the electrical elements even though the electrical elements have different height. In other words, a top surface of a structure including the electrical elements, the sensor 308 and the fillers 312 and 314 may be flattened.

In another embodiment, the top of the structure may have the same height as a top of the guide cover 310. That is, highest electrical element, the electrical element on which the filler 312 or 314 is filled, the first filler 312 and the guide cover 310 may have the same height.

The first EMI shielding layer 316 is located between the PCB substrate 304 and the lower cover 300 to protect the electrical elements from electrical noise by plasma generated in a process of manufacturing a semiconductor. Here, the first EMI shielding layer 316 may be formed by coating liquefied material or in a film type. Furthermore, the first EMI shielding layer 316 may be formed of gold, silver, copper, aluminum or their mixed material.

The first EMI shielding layer 316 may be adhered to the lower cover 300 through the first adhesive layer 318. Here, the first adhesive layer 318 may be formed of acrylic adhesive or silicone-based adhesive, etc.

The second EMI shielding layer 320 is located on the filler 312 or 314 and the highest electrical element to protect the electrical elements from electrical noise. Here, the second EMI shielding layer 320 may be formed by coating liquefied material or in a film type. Furthermore, the second EMI shielding layer 320 may be formed of gold, silver, copper, aluminum or their mixed material.

The second EMI shielding layer 320 may be adhered to the upper cover 302 through the second adhesive layer 322. Here, the second adhesive layer 322 may be formed of acrylic adhesive or silicone-based adhesive, etc.

The second monitoring device 206 locates outside the first monitoring device 204. Hereinafter, it will be assumed that the second monitoring device 206 is an edge ring, because the second monitoring device 206 can function as the edge ring.

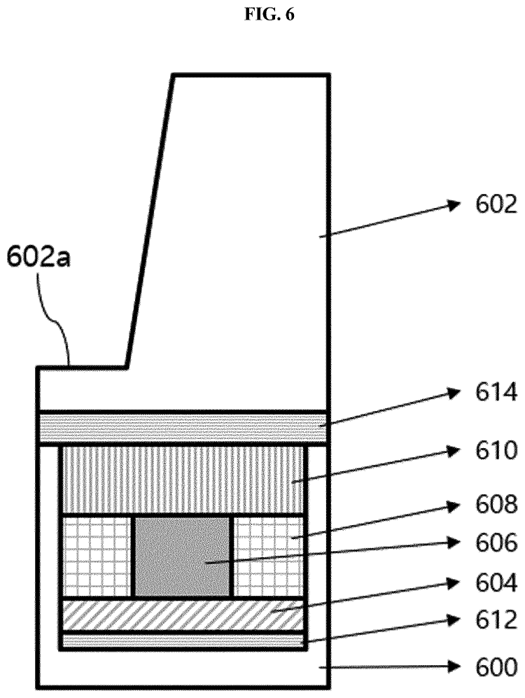

In FIG. 5 and FIG. 6, the edge ring 206 may have a circular shape and include a lower cover 600, an upper cover 602, a first circuit board 604, a first electrical element unit 606, a first filler 608 and a second filler 610.

The lower cover 600 may have ‘⊏’ shape standing vertically. That is, the lower cover 600 may include a bottom surface and lateral surfaces formed vertically at both ends of the bottom surface, and so an electrical element, etc. may be located in an internal space of the lower cover 600.

The lower cover 600 may prevent foreign substance from entering in the lower cover 600. Accordingly, structure of the lower cover 600 is not limited as long as the lower cover 600 includes the bottom surface and the lateral surfaces.

In an embodiment, the lower cover 600 may be manufactured through a laser processing or a wetting, etching, etc. so that it has an internal space wherein the electrical element, etc. can be located.

In an embodiment, the lower cover 600 may be formed of the same material as the wafer or material similar to the wafer. For example, the lower cover 600 may be formed of Si or Sic which is silicone-based material or quartz which is glass-based material. This is for smoothly delivering heat from the edge ring 206 to the wafer. However, the material of the lower cover 600 is not limited to the same material of the wafer or a material similar to the wafer.

The upper cover 602 is disposed on the lower cover 600, and it may be combined with the lower cover 600 by using an adhesive layer 614 formed of an adhesive. Of course, the combination is not limited to use the adhesive, and the combination may be variously modified as long as the upper cover 602 is combined with the lower cover 600.

Here, the adhesive may have a low outgassing feature because it is used in the chamber 200, and fluorine material with chemical resistance to etching gas may be used as the adhesive. For example, acrylic material or silicone-based material may be used as the adhesive.

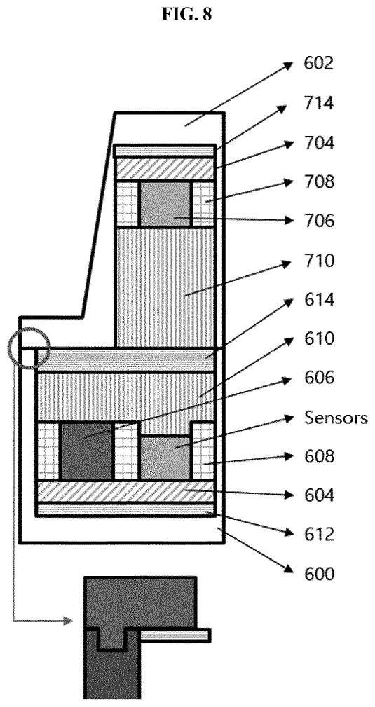

To realize the outgassing feature, a shape processing may be formed at the upper cover 602 and the lower cover 600 as shown in FIG. 8. For example, a projection may be formed on a lower surface of the upper cover 602 and a groove may be formed on an upper surface of the lower cover 600. The upper cover 602 may be combined with the lower cover 600 by inserting the projection to the groove.

The upper cover 602 may be formed of the same material as the wafer or material similar to the wafer, e.g. Si or SiC which is silicone-based material.

In an embodiment, the upper cover 602 may have a shape similar to the conventional edge ring. That is, a part 602a of a lower surface of the upper cover 602 may be flat in consideration of an outermost part of the wafer, and the other part of the upper cover 602 may be inclined from an end of the part 602a in an upward direction. As a result, the other part of the upper cover 602 except the lower part may have a width smaller than the lower cover 600, and a width of the upper cover 602 becomes narrower in a direction from the lower surface to an upper surface of the upper cover 602. Of course, the upper cover 600 may have a different shape from the conventional edge ring.

In another embodiment, chemical-resistant material or corrosion-resistant material may be coated on a surface of the upper cover 602. Here, the coated material may be ceramic material such as YOF, Al2O3, Y2O3, YAG, etc. On the other hand, this coating may be also performed on a surface of the lower cover 600.

The circuit board 604, e.g. PCB substrate may be disposed in the internal space of the lower cover 600.

In an embodiment, the circuit board 604 may be combined with a bottom surface of the lower cover 600 through an adhesive of an adhesive layer 612. Here, the adhesive may have a low outgassing feature, and fluorine material with chemical resistance to etching gas may be used as the adhesive. For example, acrylic material or silicone-based material may be used as the adhesive.

Thickness of the circuit board 604 may differ according to the thickness of the edge ring 206.

The electrical element unit 606 may be located on the circuit board 604 in an internal space of the lower cover 600 and it may include at least one electrical element.

For example, the electrical element unit 606 includes a temperature sensor for measuring temperature distribution of the lower cover 600, and it may further include one or more of a microprocessor, a wireless communication unit, a wireless charging unit, a wireless power supply, semi-solid-state or all-solid-state battery and a memory.

In an embodiment, the electrical elements may be sealed. Specifically, the electrical elements may be sealed by a first filler 608 and a second filler 610 as shown in FIG. 6. Here, an upper surface of the second filler 610 may be flat and an adhesive layer 614 may be disposed on the second filler 610.

The first filler 608 may cover the lateral surfaces, or the lateral surfaces and at least part of an upper surface of the electrical elements on the circuit board 604. The first filler 608 may make the electrical elements have the same height. For example, the first filler 608 may be filled on the other electrical elements based on the highest electrical element of the electrical elements so that the height of the other electrical elements filled by the first filler 608 is identical to that of the highest electrical element. As a result, the first filler 608 may be filled on the other electrical elements except the highest electrical element, thereby making the electrical elements have the same height.

The first filler 608 may be solid or liquid.

Si or SiC which is silicone-based material, PEEK, glass, ceramic material, quartz, etc. may be used as the first filler 608 when the first filler 608 is solid, wherein thermal expansive coefficient of PEEK, glass, ceramic material or quartz is similar to that of Si or SiC. This is to maximize sensitivity of the temperature sensor in view of heat conductivity or heat flux when the temperature is measured. However, the first filler 608 is not limited to the above material.

On the other hand, the first filler 608 may be combined with the circuit board 604 by using the adhesive mentioned above because the first filler 608 is solid.

Cured resin, e.g. epoxy or silicone-based material may be used as the first filler 608 when the first filler 608 is liquid. To form the first filler 608 with liquid is to compensate for the step difference of the electrical elements and assuring flatness of the electrical elements because the electrical elements on the circuit board 604 have different height. For example, the first filler 608 on the electrical elements may be flatten by applying a polishing process after filling the first filler 608 on the electrical elements.

On the other hand, material with low heat shrinkage rate may be used as the first filler 608 if rigidity of the first filler 608 is more than 80D when the first filler 608 is liquid.

The second filler 610 may be disposed in the range of height of highest electrical element to height of a top surface of the lower cover 600 and be solid or liquid. As a result, height of an upper part of the lower cover 600 may be identical to that of the second filler 610.

The second filler 610 may be formed of the same material as the first filler 608 or material similar to the first filler 608.

On the other hand, one filler may cover the electrical elements in an internal space of the lower cover 600.

Briefly, the edge ring 206 of the present embodiment may self-measure temperature by disposing the electrical elements such as the temperature sensor, etc. in the internal space of the lower cover 600 to perform a function of the conventional edge ring. As a result, the edge ring 206 may detect temperature characteristics of the heater 210 located below the edge ring 206 based on the measured temperature. Heating amount of the electrostatic chuck 202 or the heater 210 corresponding to the outermost part of the wafer 204 may be finetuned by using the detected result, thereby enhancing process yield.

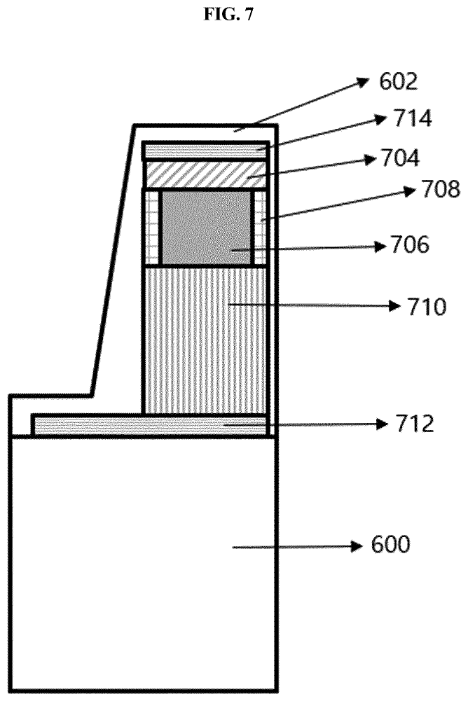

In another embodiment, the edge ring 206 may include the lower cover 600, the upper cover 602, a second circuit board 704, a second electrical element unit 706, a first filler 708, a second filler 710, a first adhesive layer 712 and a second adhesive layer 714 as shown in FIG. 7.

Unlike the embodiment in FIG. 6, electrical elements may be located in an internal space of the upper cover 602 not the lower cover 600.

The lower cover 600 may be combined with the upper cover 602 by using the first adhesive layer 712. Of course, the combination may not be limited to the method of using an adhesive of the first adhesive layer 712 and be variously modified as long as the lower cover 600 is combined with the upper cover 602.

The adhesive may be identical to or similar to the adhesive in FIG. 6.

The second filler 710 may be formed on the first adhesive layer 712 in the internal space of the upper cover 602. The second filler 710 may have the same material as the second filler 610 in FIG. 6 or material similar to the second filler 610.

The electrical elements of the electrical element unit 706 may be disposed on the second filler 710 in the internal space of the upper cover 602. Here, the electrical elements include a temperature sensor, etc.

The first filler 708 may cover a lateral surface and an upper surface of the electrical elements so that the electrical elements have the same height. Here, the first filler 708 may have the same material as the first filler 608 in FIG. 6 or material similar to the first filler 608.

The second circuit board 704 may be disposed on the electrical elements, and the circuit board 704 may be combined with an internal surface of the upper cover 602 through the second adhesive layer 714. Of course, the combination is not limited to a method of using the adhesive and may be variously modified.

The adhesive may be formed of the same material as the adhesive in FIG. 6 or material similar to the adhesive in FIG. 6.

Referring to disposition of elements in the upper cover 602 based on the upper surface of the upper cover 602, electrical elements may be disposed on the circuit board 704 and the fillers 708 and 710 may seal the electrical elements.

Shortly, in the edge ring 206 of the present embodiment, the circuit board 704 and the electrical elements may be disposed in the upper cover 602. As a result, the temperature sensor is located on an upper part of the edge ring 206. In this case, the edge ring 206 may measure distribution of heat generated when ion bombardment is applied to the wafer in plasma state of the chamber 200, with self-measuring the temperature.

In still another embodiment, In FIG. 8, the edge ring 206 of the present embodiment may include a lower cover 600, an upper cover 602, a first circuit board 604, a second circuit board 704, first electrical elements and second electrical elements. That is, the edge ring 206 of the present embodiment is a merged structure of the edge ring 206 in FIG. 6 and the edge ring 206 in FIG. 7. In the edge ring 206 of the present embodiment, the first circuit board 604 and related electrical elements are located in an internal space of the lower cover 600, and the second circuit board 704 and related electrical elements are disposed in an internal space of the upper cover 602. Elements may be formed of the same material as in above embodiments or material similar to in above embodiments.

The lower cover 600 and the upper cover 602 may be combined by using an adhesive or groove and a projection member. That is, the combination may be variously modified as long as the covers 600 and 602 are combined.

Additionally, ceramic material or polymer-based material may be coated on the upper cover 602 to prevent a surface of the upper cover 602 from being etched when an etching process is performed. Here, the coating may or may not be performed on the lower cover 600.

The first electrical elements may be formed on the first circuit board 604 and be sealed by fillers. A first temperature sensor of the first electrical elements measures temperature distribution of the lower cover 600. The first electrical elements may further include a battery, a microprocessor and so on.

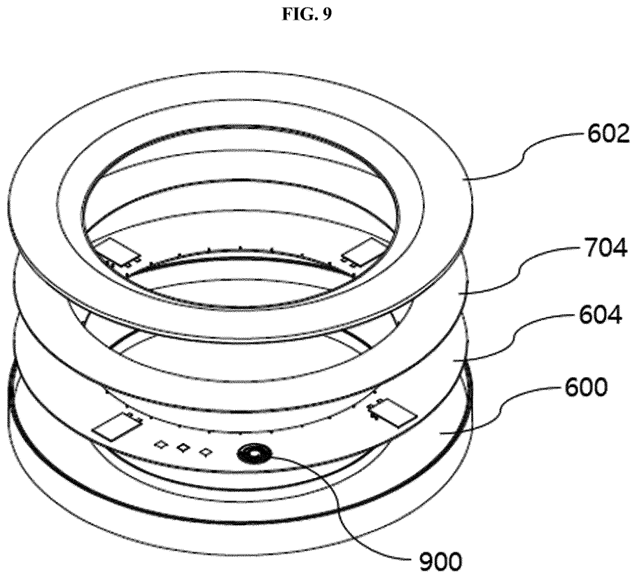

In an embodiment, an RF coil 900 may be formed on the first circuit board 604 as shown in FIG. 9. The RF coil 900 may function as a transceiver for wireless communication or a reception unit for wireless charging.

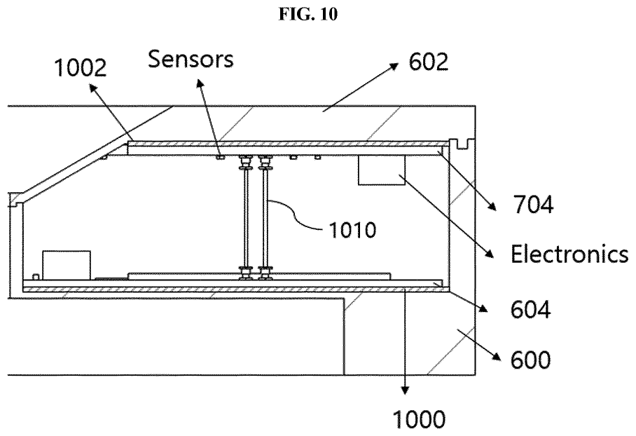

In an embodiment, the first circuit board 604 may be electrically connected to the second circuit board 704 through at least one connector 1010 as shown in FIG. 10. As a result, a power may be supplied to the other circuit board if a power supply or a battery exists on one of the circuit boards 604 and 704. The function in FIG. 8 may be achieved by applying a wireless communication method to a merged structure of a lower cover part in FIG. 6 and an upper cover part in FIG. 7, which is not shown in FIG. 9.

Fillers for sealing electrical elements may be filled in the lower cover 600 and the upper cover 602, which is not shown in FIG. 9.

In another embodiment, a filler for sealing the first electrical elements and a filler for sealing the second electrical elements don't exist independently, but a space may be formed between the circuit boards 604 and 704 and a filler may be filled in the space as shown in FIG. 10. Here, the filler may be formed of a material with high heat conductivity.

Silicone, epoxy or material with a low outgassing feature may be used as the filler when hardness or rigidity of the filler is more than 80D.

In still another embodiment, a first EMI shielding layer 1000 for protecting electrical elements from electromagnetic wave of plasma may exist between the lower cover 600 and the first circuit board 604, and a second EMI shielding layer 1002 may exist between the upper cover 602 and the second circuit board 704.

On the other hand, adhesive layers for adhering the covers 600 and 602 to the circuit boards 604 and 704 do not exist, but the EMI shielding layers 1000 and 1002 may perform an adhering function as well as a shielding function from an electromagnetic wave.

In brief, the edge ring 206 of the present embodiment includes a temperature sensor located at its upper part and a temperature sensor located at its lower part to measure temperature of the upper part and temperature of the lower part. In this case, the edge ring 206 may measure heat flux from the upper part to the lower part or heat flux from the lower part to the upper part as well as temperature distribution of the covers 600 and 602.

The heating amount of the electrostatic chuck 202 corresponding to the outermost part of the wafer may be finetuned or adjusted if the edge ring 206 measures the temperature distribution or the heat flux. That is, heat may be uniformly applied to the wafer by adjusting heaters for heating the electrostatic chuck 202 and the heater 210 below the edge ring 206. As a result, the process yield of the wafer may be enhanced.

The upper cover and the lower cover exist independently in above embodiments, but the upper cover and the lower cover may be integrally formed.

In the above description, the second monitoring device 206 is referred to as the edge ring. However, the edge ring and the second monitoring device 206 exist independently, and the second monitoring device 206 may measure a process parameter of the edge ring while being disposed on the edge ring. Here, the second monitoring device 206 may include at least one electrical element and a sensor and the electrical element or the sensor may be seal by a filler.

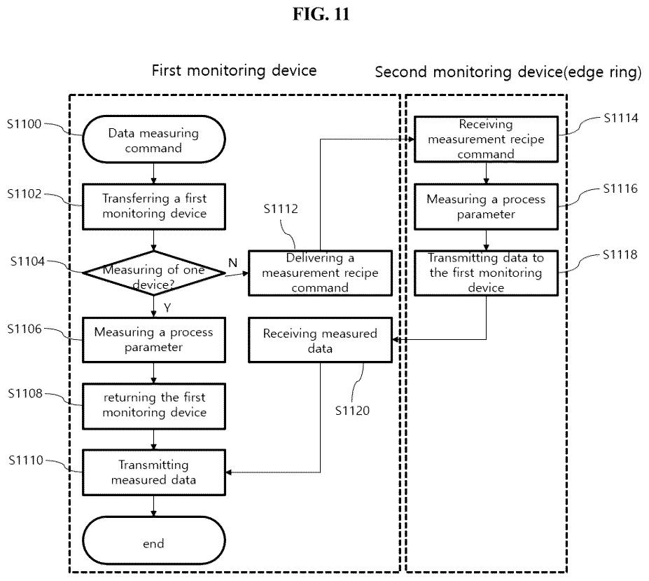

FIG. 11 is a flowchart illustrating a process of measuring a process parameter in a monitoring system according to an embodiment of the present disclosure.

Generally, a wafer is transferred in a chamber and is returned outside the chamber in every semiconductor process, but the edge ring (second monitoring device, 206) is exchanged only when a problem occurs in the chamber or only when a component is changed. Hence, the first monitoring device 204 disposed on the chuck 202 may be transferred in the chamber and be returned outside the chamber during each process, and the second monitoring device 206 may be continuously used during several processes. FIG. 11 shows a process of measuring a process parameter in this environment.

If data measuring command is inputted in a step of S1100, the first monitoring device 204 is transferred in the chamber 200 in a step of S1102. Particularly, the first monitoring device 204 is disposed on the chuck 202 on which the wafer is to be disposed in a later process.

In an embodiment, the first monitoring device 204 may include measurement recipe information for the second monitoring device 206.

In a step of S1104, it is discriminated whether only the first monitoring device 204 measures a process parameter. Of course, this discrimination may be predetermined when the first monitoring device 204 is transferred.

In a step of S1106, the first monitoring device 204 may measure the process parameter, e.g. temperature distribution of the chuck 202 when it is determined that only the first monitoring device 204 measures the process parameter.

In a step of S1108, the first monitoring device 204 is returned outside the chamber 200 when the first monitoring device 204 obtains data. In a step of S1110, the first monitoring device 204 may transmit data concerning the measured process parameter to an external device, e.g. a station of a wafer cassette or a management server. This operation will be described in detail below.

In a step of S1114, the first monitoring device 204 may transmit a measurement recipe command included in the measurement recipe information to the second monitoring device 206 when measurement of the second monitoring device 206 as well as the first monitoring device 204 is required.

In a step of S1116, the second monitoring device 206 is changed from a standby mode to a measurement mode according to the transmitted measurement recipe command, and then measure self-process parameter, e.g. temperature distribution.

In a step of S1118, the second monitoring device 206 transmits measured data concerning measured process parameter to the first monitoring device 204. As a result, the first monitoring device 204 may include self-measured data and the data measured by the second monitoring device 206.

In a step of S1110, the first monitoring device 204 may transmit at least one of the data to an external device.

Briefly, in the monitoring system of the present embodiment, the first monitoring device 204 includes the measurement recipe information for controlling the second monitoring device 206, the second monitoring device 206 transmits the measured data to the first monitoring device 204, and the first monitoring device 204 may transmit self-measured data and the data measured by the second monitoring device 206 to the external device.

In another embodiment, the second monitoring device 206 may be activated in response to the measurement recipe command transmitted from the first monitoring device 204, and it does not transmit the measured data to the first monitoring device 204 but may transmit directly the measured data to the external device. However, it is efficient that the data measured by the second monitoring device 206 is transmitted to the external device through the first monitoring device 204, considering communication architecture of the monitoring system.

In the above description, the second monitoring device 206 is used as the edge ring. However, an extra edge ring exists, and the second monitoring device 206 may be located on the edge ring and measure a process parameter of the edge ring.

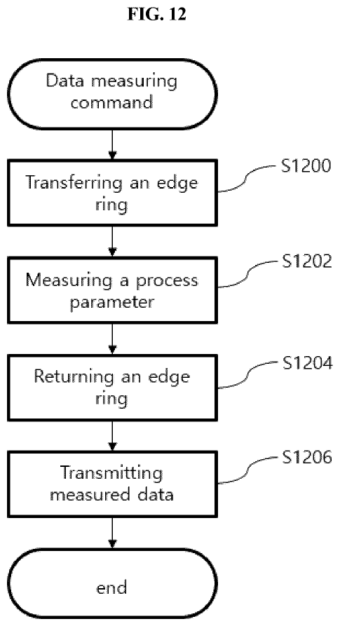

FIG. 12 is a flowchart illustrating a process of measuring a process parameter in a monitoring system according to another embodiment of the present disclosure. FIG. 12 shows a monitoring process when only an edge ring is located in the chamber 200.

In FIG. 12, an edge ring 206 is transferred in the chamber 200 according to a data measurement command in a step of S1200. Particularly, the edge ring 206 is located outside the chuck 202 in the chamber 200.

The edge ring 206 measures its process parameter in a step of S1202 and then is returned outside the chamber 200 in a step of S1204.

In a step of S1206, the edge ring 206 may transmit the measured data to the external device.

Shortly, the edge ring 206 may measure the process parameter after it is transferred in the chamber 200, and then returned outside the chamber 200. Subsequently, the edge ring 206 may transmit the measured data to the external device.

On the other hand, if the second monitoring device and the edge ring 206 exist independently, the second monitoring device may measure a process parameter of the edge ring 206 after being transferred in the chamber 200, be returned outside the chamber 200, and then transmit the measured data to the external device.

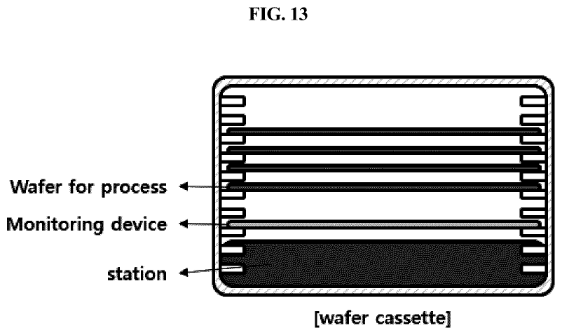

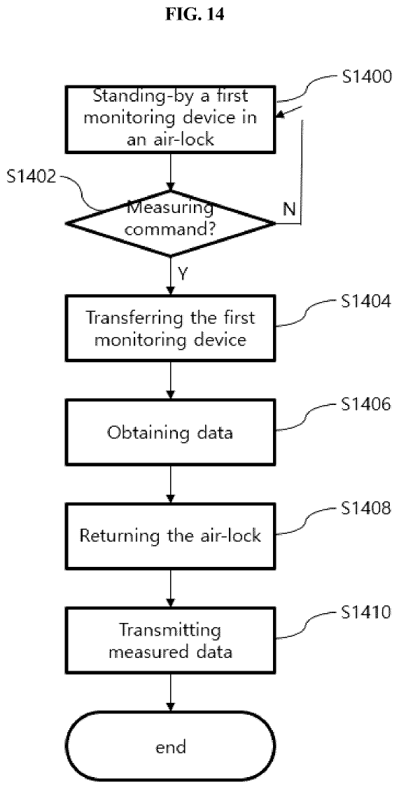

FIG. 13 is a sectional view illustrating a wafer cassette according to an embodiment of the present disclosure, and FIG. 14 is a flowchart illustrating operation of the wafer cassette in FIG. 13.

In FIG. 13, the wafer cassette of the present embodiment may exist in an air-lock chamber of a semiconductor facility and include plural slits.

In an embodiment, a wafer and the monitoring device 204 or 206 may be laid on part of the slits of the wafer cassette, and a station may be located at the lowest area of the wafer cassette. Preferably, the monitoring device 204 or 206 may be located on a lower part of the wafer cassette, and one or more wafers may be disposed on a slit located above a slit on which the monitoring device 204 or 206 locates.

The station may apply a power to the monitoring device 204 or 206, receive the measured data from the monitoring device 204 or 206 and transmit the received measured data to the external device. For example, the station may be electrically connected to semiconductor equipment and transmit the measured data to the semiconductor equipment.

Specifically, a robot handler transfers the monitoring device 204 or 206 from the air-lock chamber to the process chamber 200 in a step of S1404, if a user inputs a measuring command by using the semiconductor equipment while the monitoring device 204 or 206 stands-by in the wafer cassette in steps of S1400 and S1402.

The monitoring device 204 or 206 measures the process parameter according to a recipe set by the user and is laid in the wafer cassette after being returned to the air-lock chamber when the measuring is completed. In this case, the monitoring device 204 or 206 may be automatically charged by the station.

In a step of S1410, the monitoring device 204 or 206 may transmit the measured data to the station of the wafer cassette, and the station may transmit the transmitted measured data to the semiconductor equipment.

In brief, the monitoring device 204 or 206 may transmit the measured data to the external device through the station while in the wafer cassette, and it may be charged by the station.

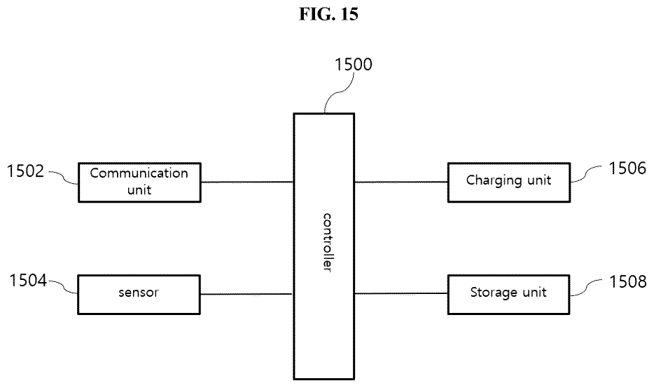

FIG. 15 is a block diagram illustrating a first monitoring device according to an embodiment of the present disclosure.

In FIG. 15, the first monitoring device 204 may include a controller (microprocessor) 1500, a communication unit 1502, a sensor 1504, a charging unit 1506 and a storage unit (memory) 1508.

The communication unit 1502 is a communication path with the external device, the station in the wafer cassette or the second monitoring device 206.

The sensor 1504 measures the process parameter of the chuck 202.

The charging unit 1506 charges wirelessly through, for example, the station.

The storage unit 1508 may store various data such as the measurement recipe information, the measured data, etc.

The controller 1500 controls operation of elements in the first monitoring device 204. For example, the controller 1500 may transmit the measurement recipe command included in the measurement recipe information to the second monitoring device 206 and transmit self-measured first measured data or second measured data provided from the second monitoring device 206 to the station or the external device.

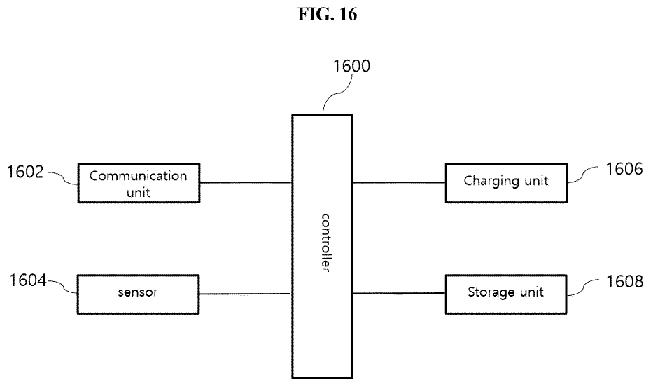

FIG. 16 is a block diagram illustrating a second monitoring device according to an embodiment of the present disclosure.

In FIG. 16, the second monitoring device 206 may include a controller (microprocessor) 1600, a communication unit 1602, a sensor 1604, a charging unit 1606 and a storage unit (memory) 1608.

The communication unit 1602 is a communication path with the external device, the station of the wafer cassette or the first monitoring device 204.

The sensor 1604 measures a self-process parameter or a process parameter of the edge ring.

The charging unit 1606 charges wirelessly through, for example, the station.

The storage unit 1608 may store various data such as the measured data, etc.

The controller 1600 controls an operation of elements of the second monitoring device 206. For example, the controller 1600 may control the sensor 1604 to measure the process parameter in response to the measurement recipe command received from the first monitoring device 204 and transmit the measured data to the first monitoring device 204, the station or the external device.

Components in the embodiments described above can be easily understood from the perspective of processes. That is, each component can also be understood as an individual process. Likewise, processes in the embodiments described above can be easily understood from the perspective of components.

Also, the technical features described above can be implemented in the form of program instructions that may be performed using various computer means and can be recorded in a computer-readable medium. Such a computer-readable medium can include program instructions, data files, data structures, etc., alone or in combination. The program instructions recorded on the medium can be designed and configured specifically for the present invention or can be a type of medium known to and used by the skilled person in the field of computer software. Examples of a computer-readable medium may include magnetic media such as hard disks, floppy disks, magnetic tapes, etc., optical media such as CD-ROM's, DVD's, etc., magneto-optical media such as floptical disks, etc., and hardware devices such as ROM, RAM, flash memory, etc. Examples of the program of instructions may include not only machine language codes produced by a compiler but also high-level language codes that can be executed by a computer through the use of an interpreter, etc. The hardware mentioned above can be made to operate as one or more software modules that perform the actions of the embodiments of the invention, and vice versa.

The embodiments of the invention described above are disclosed only for illustrative purposes. A person having ordinary skill in the art would be able to make various modifications, alterations, and additions without departing from the spirit and scope of the invention, but it is to be appreciated that such modifications, alterations, and additions are encompassed by the scope of claims set forth below.

1. A first monitoring device used in a monitoring system, the first
monitoring device comprising:
a sensor configured to measure a process parameter;
a communication unit; and
a controller,
wherein the first monitoring device is located on an object to be monitored and measures the process parameter of the object using the sensor, an edge ring is disposed outside the object,
the controller transmits a measurement recipe command for requesting measuring of a process parameter of the edge ring to the edge ring or a second monitoring device for measuring the process parameter of the edge ring through the communication unit, and the measurement recipe command is a command of controlling the edge ring or the second monitoring device so that the edge ring or the second monitoring device measures the process parameter of the edge ring.

2. The first monitoring device of claim 1, wherein the object is a chuck, and the first monitoring device includes measurement recipe information related to the measurement recipe command before the first monitoring device is transferred in a chamber,
and wherein the first monitoring device transmits at least one of first measured data obtained by measuring the process parameter of the chuck and second measured data concerning the process parameter of the edge ring provided from the edge ring or the second monitoring device to an external device after the first monitoring device is laid in a cassette.

3. The first monitoring device of claim 2, wherein a wafer and the first monitoring device are laid in the cassette and the cassette further includes a station,
and wherein the first monitoring device transmits one or more of the measured data to the station, the station provides the transmitted measured data to a semiconductor equipment connected electrically thereto, and the first monitoring device is wirelessly charged by the station.

4. The first monitoring device of claim 1, further comprising:
an upper cover;
a lower cover;
a circuit board disposed between the upper cover and the lower cover; and
a guide cover,
wherein the sensor, the communication unit and the controller are located on the circuit board, the guide cover is disposed at a side of the circuit board,
a first filler is filled one or more of a space between the sensor and the communication unit, a space between the communication unit and the controller, a space between the sensor and the controller or a space between the sensor and a second filler is filled on the sensor, the communication unit or the controller, and at least one of the sensor, the communication unit and the controller is sealed by the fillers.

5. The first monitoring device of claim 4, wherein each of the upper cover, the lower cover and the guide cover is formed of the same material as a silicone wafer, silicone carbide, sapphire, Y₂O₃, YOF or Al₂O₃ which is silicone-based material, Teflon which is an engineering plastic, PEEK or carbon fiber.

6. The first monitoring device of claim 4, wherein a height of the highest element of the first filler, the second filler, the sensor, the communication unit and the controller is identical to a height of the guide cover, and at least one of sensors is located in an extreme edge area.

7. The first monitoring device of claim 4, further comprising:
a first EMI shielding layer located between the circuit board and the lower cover;
a first adhesive layer configured to adhere the first EMI shielding layer to the lower cover;
a second EMI shielding layer disposed on the first filler and the second filler; and
a second adhesive layer configured to adhere the second EMI shielding layer to the upper cover,
wherein acrylic material or silicone-based material is used as an adhesive of the adhesive layers.

8. The first monitoring device of claim 4, wherein the first filler is solid and the second filler is liquid,
and wherein silicone-based material, PEEK, glass, ceramic material or quartz is used as the first filler, and epoxy or silicone-based material is used as the second filler.

9. A second monitoring device used in a monitoring system, the second monitoring device comprising:
a sensor configured to measure a process parameter;
a communication unit; and
a controller,
wherein the second monitoring device is an edge ring disposed outside a chuck and communicates with a first monitoring device for measuring a process parameter of a chuck with disposed on the chuck,
the controller controls the sensor to measure the process parameter in response to a measurement recipe command transmitted from the first monitoring device through the communication unit, and transmits measured data concerning the measured process parameter to the first monitoring device or an external device.

10. The second monitoring device of claim 9, further comprising:
an upper cover configured to have a first internal space;
a lower cover configured to have a second internal space and combined with a lower part of the upper cover;
a first circuit board and a first sensor disposed sequentially in the first internal space; and
a second circuit board and a second sensor disposed sequentially in the second internal space,
wherein a filler seals the first sensor on the first circuit board, and
another filler seals the second sensor on the second circuit board.

11. The second monitoring device of claim 10, wherein first electrical elements other than the first sensor are disposed on the first circuit board, and second electrical elements other than the second sensor locate on the second circuit board,
and wherein the filler covers electrical elements lower than the highest electrical element of the first sensor and the first electrical elements based on the highest electrical element, and
another filler covers electrical elements lower than the highest electrical element of the second sensor and the second electrical elements based on the highest electrical element.

12. The second monitoring device of claim 11, wherein the filler or the another filler is solid or liquid,
and wherein silicone-based material, PEEK, glass, ceramic material or quartz is used as the solid, and epoxy or silicone-based material is used as the liquid.

13. The second monitoring device of claim 10, wherein the first circuit board and the second circuit board are electrically connected through at least one connector, and a power is applied from another circuit board to one of the circuit boards.

14. A method of measuring a process parameter in a monitoring system which includes a first monitoring device disposed on an object to be monitored and a second monitoring device located outside the object and functioning as an edge ring, the method comprising:
disposing the first monitoring device on the object;
transmitting for the first monitoring device a measurement recipe command to the second monitoring device;
measuring for the second monitoring device self-process parameter in response to the transmitted measurement recipe command;
transmitting second measured data concerning the measured process parameter from the second monitoring device to the first monitoring device; and
transmitting for the first monitoring device the transmitted second measured data to an external device.

15. The method of claim 14, wherein the object is a chuck, the first monitoring device is exchanged each process, and the second monitoring device exists in a chamber during several processes,
the method further comprising:
measuring for the first monitoring device a process parameter of the chuck; and
transmitting for the first monitoring device first measured data concerning the measured process parameter to the external device.

16. The method of claim 14, wherein the step of transmitting the transmitted second measured data includes:
returning the first monitoring device to a cassette after the first monitoring device receives the second measured data;
transmitting for the first monitoring device the second measured data to a station of the cassette; and
transmitting for the station the transmitted second measured data to a semiconductor equipment connected electrically to the station.

17. The method of claim 14, wherein the first monitoring device is transferred in a chamber and is located on the object,
and wherein the first monitoring device receives information concerning the measurement recipe command from a station of a cassette before the first monitoring device is transferred in the chamber, and the first monitoring device transmits the second measured data to the station after the first monitoring device is returned outside the chamber.

18. A cassette used in a monitoring system comprising:
slits; and
a station,
wherein the monitoring device is laid on the slit and measures a process parameter of an object in a chamber, and the station receives measured data concerning the measured process parameter from the monitoring device and transmits the received measured data to an external device.

19. The cassette of claim 18, wherein a wafer is laid on the slits, the station charges wirelessly the monitoring device, and
the station transmits the measured data to semiconductor equipment connected electrically to the station.
